(19) United States
(12) Patent Application Publication
(10) Pub. No.: US 2011/0249535 A1
(43) Pub. Date: Oct. 13, 2011

(54) METHOD OF MANUFACTURING PIEZOELECTRIC VIBRATOR, OSCILLATOR, ELECTRONIC DEVICE, AND RADIO-CONTROLLED TIMEPIECE

(76) Inventors: Yoichi Funabiki, Chiba-shi (JP); Masashi Numata, Chiba-shi (JP); Kazuyoshi Sugama, Chiba-shi (JP)

(21) Appl. No.: 13/167,283

(22) Filed: Jun. 23, 2011

Related U.S. Application Data
(63) Continuation of application No. PCT/JP2009/053333, filed on Feb. 25, 2009.

(51) Int. Cl. G04F 5/06; G04C 11/02; H01L 41/22; H03B 5/36

(52) U.S. Cl. 368/47; 331/158; 368/159; 29/25.35

(57) ABSTRACT

A method of manufacturing a piezoelectric vibrator according to the invention includes the steps of: inserting a core portion of a conductive rivet member, which includes a planar base portion and the core portion extending in a direction vertical to the surface of a base portion, into a penetration hole of the base substrate and bringing the base portion of the rivet member into contact with a first surface of the base substrate; applying a paste-like glass frit on a second surface of the base substrate and moving a first squeegee which comes into contact with the second surface with an attack angle in one direction to thereby fill the glass frit in the penetration hole; and moving a second squeegee which comes into contact with the second surface with an attack angle in a direction opposite to the one direction to thereby fill the glass frit applied redundantly on the second surface in the penetration hole.

### RELATED APPLICATIONS

This application is a continuation of PCT/W2009/053333 filed on Feb. 25, 2009. The entire content of this application is incorporated herein by reference.

### BACKGROUND OF THE INVENTION

1. Field of the Invention

The present invention relates to a method of manufacturing a surface mounted device (SMD)-type piezoelectric vibrator in which a piezoelectric vibrating reed is sealed in a cavity formed between two bonded substrates, and an oscillator, an electronic device, and a radio-controlled timepiece each having the piezoelectric vibrator.

2. Description of the Related Art

In recent years, a piezoelectric vibrator utilizing quartz or the like has been used in mobile phones and mobile information terminals as the time source, the timing source of a control signal, a reference signal source, and the like. Although there are various piezoelectric vibrators of this type, a surface mounted device-type piezoelectric vibrator is known as one example thereof. As the piezoelectric vibrator of this type, generally, a three-layered piezoelectric vibrator in which a piezoelectric substrate having a piezoelectric vibrating reed formed thereon is bonded so as to be interposed from above and below by the base substrate and a lid substrate is known. In this case, the piezoelectric vibrator is accommodated in a cavity (sealed space) that is formed between the base substrate and the lid substrate. Moreover, in recent years, instead of the three-layered piezoelectric vibrator, a two-layered piezoelectric vibrator has also been developed.

The piezoelectric vibrator of this type has a two-layer structure in which a base substrate and a lid substrate are directly bonded, and a piezoelectric vibrating reed is accommodated in a cavity formed between the two substrates.

The two-layered piezoelectric vibrator is ideally used as it is superior in achieving a thin profile compared with the three-layered structure. As an example of such a two-layered piezoelectric vibrator, a piezoelectric vibrator in which a piezoelectric vibrating reed is electrically connected to external electrodes formed on a base substrate using a conductive member which is formed so as to penetrate through the base substrate is known (for example, see Patent Citations 1 and 2).

This piezoelectric vibrator 200 includes a base substrate 201 and a lid substrate 202 which are anodically bonded to each other by a bonding film 207 and a piezoelectric vibrating reed 203 which is sealed in a cavity C formed between the two substrates 201 and 202, as shown in FIGS. 24 and 25. The piezoelectric vibrating reed 203 is a tuning-fork type vibrating reed, for example, and is mounted on the upper surface of the base substrate 201 in the cavity C by a conductive adhesive E.

The base substrate 201 and the lid substrate 202 are insulating substrates, for example, made of ceramics, glass, and the like. Among the two substrates 201 and 202, through holes 204 are formed on the base substrate 201 so as to penetrate through the base substrate 201. Moreover, a conductive member 205 is embedded in the through holes 204 so as to block the through holes 204. The conductive member 205 is electrically connected to external electrodes 206 which are formed on the lower surface of the base substrate 201 and is electrically connected to the piezoelectric vibrating reed 203 mounted in the cavity C.

### Patent Citation 1: JP-A-2001-267190

### Patent Citation 2: JP-A-2007-328941

In the two-layered type piezoelectric vibrator, the conductive member 205 performs two major roles of blocking the through holes 204 to maintain the airtightness in the cavity C and electrically connecting the piezoelectric vibrating reed 203 and the external electrode 206 to each other. In particular, if the contact between the conductive member 205 and the through holes 204 is not sufficient, there is a possibility that the airtightness in the cavity C is impaired. Moreover, if the contact between the conductive member 205 and the conductive adhesive E or the external electrode 206 is not sufficient, the piezoelectric vibrating reed 203 will not operate properly. Therefore, in order to eliminate such a problem, it is necessary to form the conductive member 205 in a state where the conductive member 205 is tightly and closely adhered to the inner surfaces of the through holes 204 to completely block the through holes 204, and no depression or the like appears on the surface.

Patent Citations 1 and 2 describe that the conductive member 205 is formed using a conductive paste (an Ag paste, an Au—Sn paste, or the like). However, there is no description as to a specific manufacturing method such as how to form the conductive member.

In general, when a conductive paste is used, it is necessary to perform baking to cure the conductive paste. That is, it is necessary to perform baking to cure the conductive paste after it is filled in the through holes 204. However, when baking is performed, since organic materials included in the conductive paste are removed through evaporation, the volume of the conductive paste after baking generally decreases compared to the volume of the conductive paste before baking (for example, the volume decreases approximately 20% when an Ag paste is used as the conductive paste). Therefore, even when the conductive member 205 is formed using the conductive paste, there is a possibility that depressions appear on the surface, or in severe cases, the centers of the penetration holes are opened.

As a result, there is a possibility that the airtightness in the cavity C is impaired, or the electrical connection between the piezoelectric vibrating reed 203 and the external electrode 206 is impaired.

In order to solve the problems described above, a method of forming a penetration electrode as below is proposed. That is, as shown in FIG. 26A, first, a pin 212 made of metal is disposed in a through hole 211 formed on a base substrate 201. Subsequently, as shown in FIG. 26B, a filling squeegee 214 inclined at an attack angle γ° (for example, 15°) with respect to the surface of the base substrate 201 is brought into contact with the surface of the base substrate 201 and is then moved in one direction, whereby a paste-like glass frit 215 on the base substrate 201 is filled in the through hole 211 (setting step). Subsequently, a scribing squeegee 216 inclined at an attack angle δ° (for example, 85°) larger than the attack angle γ° with respect to the surface of the base substrate 201 is moved in the opposite direction to the movement direction of the filling squeegee 214 to thereby remove the redundant glass frit 215 remaining on the base substrate 201 (glass frit removal step). In this way, by filling the glass frit 215 into the gap between the through hole 211 and the pin 212 and then performing baking to form a penetration electrode, the volume decrease occurs only in a portion of the glass frit 215. Thus, it is possible to shorten the time for a subsequent polishing step and to effectively form a penetration electrode.

However, as described above, if the glass frit 215 is filled using the filling squeegee 214 and the scribing squeegee 216, the glass frit 215 is not filled on the back surface side of the pin 212 in the movement direction of the filling squeegee 214, and thus, depressions D are formed (see FIG. 26C). In this case, although the scribing squeegee 216 moves in the opposite direction to the movement direction of the filling squeegee 214 while scraping the glass frit 215 remaining on the base substrate 201, since the attack angle δ is large, the scribing squeegee 216 is unable to guide the glass frit 215 into the depressions D. As a result, as shown in FIG. 26D, the depressions D remain in the glass frit 215 in the through hole 211. If the depressions D are formed, cracks occur easily, and there is a possibility that the airtightness in the cavity C is impaired or the electrical connection between the piezoelectric vibrating reed 203 and the external electrode 206 is impaired.

### SUMMARY OF THE INVENTION

The invention has been made in view of the above problems, and an object of the invention is to provide a method of manufacturing a piezoelectric vibrator capable of securing airtightness in a cavity and a stable electrical connection between a piezoelectric vibrating reed and an external electrode, an oscillator, an electronic device, and a radio-controlled timepiece.

In order to solve the problems, the invention provides the following means.

That is, a method of manufacturing a piezoelectric vibrator according to the invention is a method of manufacturing a piezoelectric vibrator in which a piezoelectric vibrating reed is sealed in a cavity formed between a base substrate and a lid substrate bonded to each other, the method including the steps of inserting a core portion of a conductive rivet member, which includes a planar base portion and the core portion extending in a direction vertical to the surface of the base portion, into a penetration hole of the base substrate and bringing the base portion of the rivet member into contact with a first surface of the base substrate; applying a paste-like glass frit on a second surface of the base substrate and moving a first squeegee which comes into contact with the second surface with an attack angle along the second surface in one direction from one side of the penetration hole to thereby fill the glass frit in the penetration hole; moving a second squeegee which comes into contact with the second surface with an attack angle along the second surface in a direction opposite to the one direction from the opposite side with the penetration hole on one side disposed therebetween to thereby fill the glass frit applied redundantly on the second surface in the penetration hole; and baking and curing the glass frit.

According to the method of manufacturing the piezoelectric vibrator having such a configuration, by performing a filling operation in two steps wherein a glass frit is filled in a penetration hole from one side using a first squeegee, and a second squeegee is moved in a direction opposite to the movement direction of the first squeegee from the opposite side to thereby fill the glass frit in the penetration hole, it is possible to reliably fill the glass frit so that the inside of the penetration hole is filled with the glass frit.

Moreover, in the method of manufacturing the piezoelectric vibrator according to the invention, the attack angles of the first and second squeegees may be set to be within the range of 5° to 45°.

By moving the first and second squeegees coming into contact with the second surface of the base substrate at such an attack angle, it is possible to fill the glass frit in the penetration hole in a more reliable manner.

Furthermore, in the method of manufacturing the piezoelectric vibrator according to the invention, the first and second squeegees may include an attack surface which is inclined at the attack angle and comes into contact with the second surface, and an escape surface which is gradually inclined upward as it advances toward a rear side in the movement directions of the first and second squeegees from a contact portion between the second surface and the attack surface.

When the operation of filling the glass frit is performed using the first and second squeegees having such a shape, it is possible to reliably fill the glass frit in the penetration hole. Moreover, since the escape surface is formed, it is possible to decrease the resistance when moving the first and second squeegees and to perform the filling operation smoothly.

An oscillator according to the invention includes the piezoelectric vibrator manufactured by any one of the above-described methods which is electrically connected to an integrated circuit as an oscillating piece.

According to the oscillator having such a configuration, since electrodes are formed by reliably filling the glass frit in the penetration hole, it is possible to secure the airtightness in a cavity or the electrical connection between a piezoelectric vibrating reed and an external electrode.

An electronic device according to the invention includes the piezoelectric vibrator manufactured by any one of the above-described methods which is electrically connected to a clock section.

According to the electronic device having such a configuration, since electrodes are formed by reliably filling the glass frit in the penetration hole, it is possible to secure the airtightness in a cavity or the electrical connection between a piezoelectric vibrating reed and an external electrode.

A radio-controlled timepiece according to the invention includes a piezoelectric element manufactured by any one of the above-described methods which is electrically connected to a filter section.

According to the radio-controlled timepiece having such a configuration, since electrodes are formed by reliably filling the glass frit in the penetration hole, it is possible to secure the airtightness in a cavity or the electrical connection between a piezoelectric vibrating reed and an external electrode.

According to the method of manufacturing the piezoelectric vibrator according to the invention, by filling the glass frit in the penetration hole in two steps using the first and second squeegees, it is possible to secure the airtightness in a cavity or the electrical connection between a piezoelectric vibrating reed and an external electrode.

### BRIEF DESCRIPTION OF THE DRAWINGS

FIG. 1 is a perspective view showing an external appearance of a piezoelectric vibrator according to an embodiment of the invention.

FIG. 2 is a top view showing an inner structure of the piezoelectric vibrator shown in FIG. 1 when a piezoelectric vibrating reed is viewed from above with a lid substrate removed.

FIG. 3 is a cross-sectional view of the piezoelectric vibrator taken along the line A-A shown in FIG. 2.

FIG. 4 is an exploded perspective view of the piezoelectric vibrator shown in FIG. 1.

FIG. 5 is a top view of the piezoelectric vibrating reed that constitutes the piezoelectric vibrator shown in FIG. 1.

FIG. 6 is a bottom view of the piezoelectric vibrating reed shown in FIG. 5.

FIG. 7 is a cross-sectional view taken along the line B-B shown in FIG. 5.

FIG. 8 is a perspective view of a cylindrical member that forms a penetration electrode shown in FIG. 3.

FIG. 9 is a flowchart showing the flow of the process of manufacturing the piezoelectric vibrator shown in FIG. 1.

FIG. 10 is a view showing one step of the process of manufacturing the piezoelectric vibrator in accordance with the flowchart shown in FIG. 9, showing a state where a plurality of recesses is formed on a lid substrate wafer serving as a base material of a lid substrate.

FIG. 11 is a view showing one step of the process of manufacturing the piezoelectric vibrator in accordance with the flowchart shown in FIG. 9, showing a state where a pair of through holes is formed on a base substrate wafer serving as a base material of a base substrate.

FIG. 12 is a view showing the state shown in FIG. 11 when the state is viewed from the section of the base substrate wafer.

FIG. 13 is a perspective view of a rivet member used for manufacturing the piezoelectric vibrator in accordance with the flowchart shown in FIG. 9.

FIGS. 14A to 14D are views showing one step of the process of manufacturing the piezoelectric vibrator in accordance with the flowchart shown in FIG. 9, showing a step of disposing the rivet member in the through hole and filling a glass frit in the through hole.

FIG. 15 is a top view showing a state where the glass frit is filled in the through hole using a first squeegee.

FIG. 16 is a view showing one step of the process of manufacturing the piezoelectric vibrator in accordance with the flowchart shown in FIG. 9, showing a state where the glass frit is baked, subsequent to the state shown in FIG. 15.

FIG. 17 is a view showing one step of the process of manufacturing the piezoelectric vibrator in accordance with the flowchart shown in FIG. 9, showing a state where a base portion of the rivet member is polished, subsequent to the state shown in FIG. 16.

FIG. 18 is a view showing one step of the process of manufacturing the piezoelectric vibrator in accordance with the flowchart shown in FIG. 9, showing a state where a bonding film and a lead-out electrode are patterned on the upper surface of the base substrate wafer, subsequent to the state shown in FIG. 17.

FIG. 19 is an overall view of the base substrate wafer in the state shown in FIG. 18.

FIG. 20 is an exploded perspective view showing one step of the process of manufacturing the piezoelectric vibrator in accordance with the flowchart shown in FIG. 9 and is an exploded perspective view of a wafer assembly in which the base substrate wafer and the lid substrate wafer are anodically bonded with the piezoelectric vibrating reed accommodated in the cavity.

FIG. 21 is a view showing the configuration of an oscillator according to an embodiment of the invention.

FIG. 22 is a view showing the configuration of an electronic device according to an embodiment of the invention.

FIG. 23 is a view showing the configuration of a radio-controlled timepiece according to an embodiment of the invention.

FIG. 24 is a top view showing an inner structure of a piezoelectric vibrator according to the related art when a piezoelectric vibrating reed is viewed from above with a lid substrate removed.

FIG. 25 is a cross-sectional view of the piezoelectric vibrator shown in FIG. 24.

FIGS. 26A to 26D are views showing one step of the process of manufacturing the piezoelectric vibrator according to the related art, showing a step of disposing a rivet member in a through hole, filling a glass frit using a filling squeegee, and removing the redundant glass frit using a scribing squeegee.

### DETAILED DESCRIPTION OF THE PREFERRED EMBODIMENTS

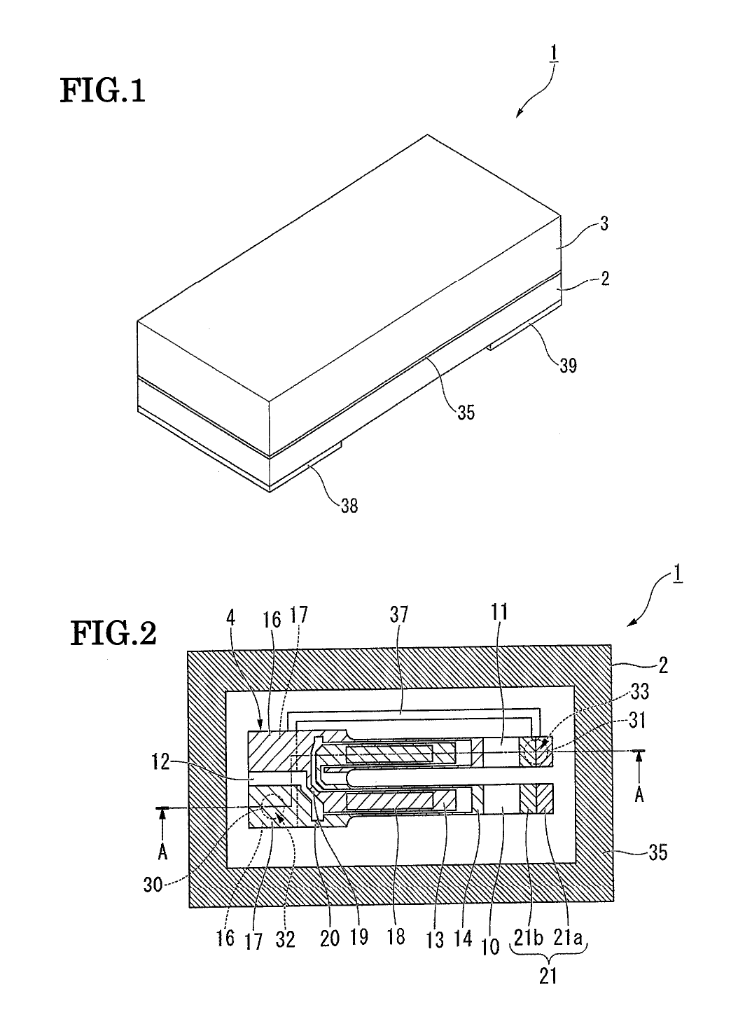

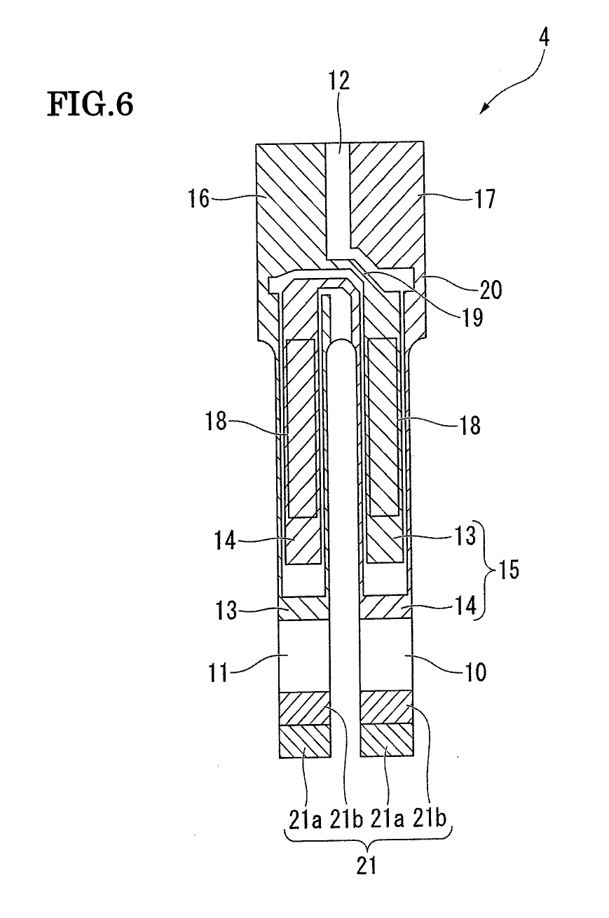

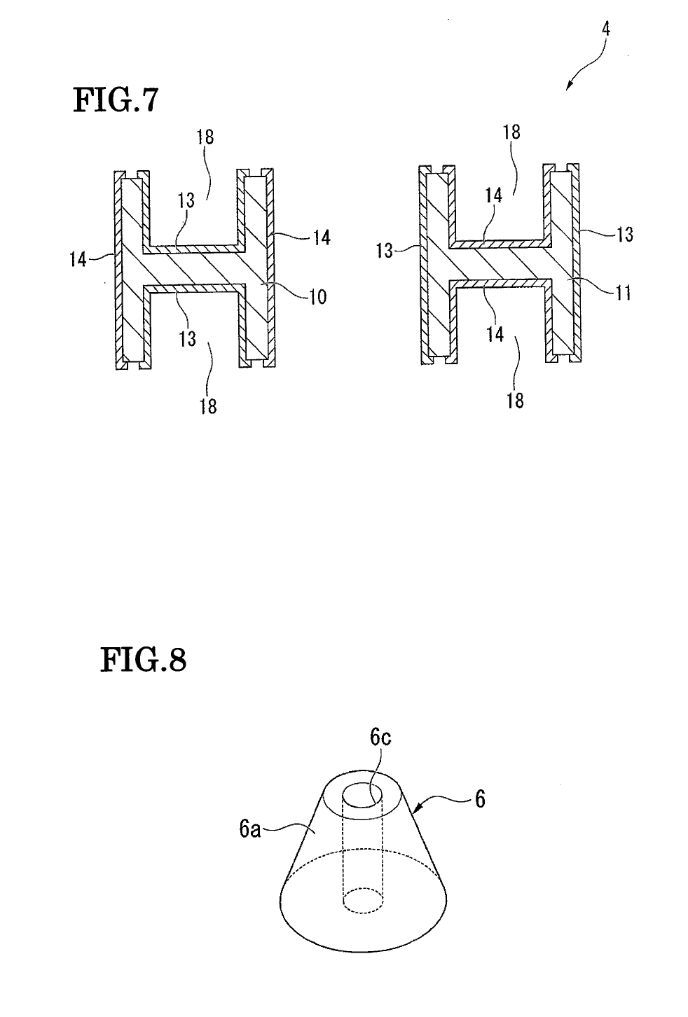

Hereinafter, an embodiment of the invention will be described with reference to FIGS. 1 to 20.

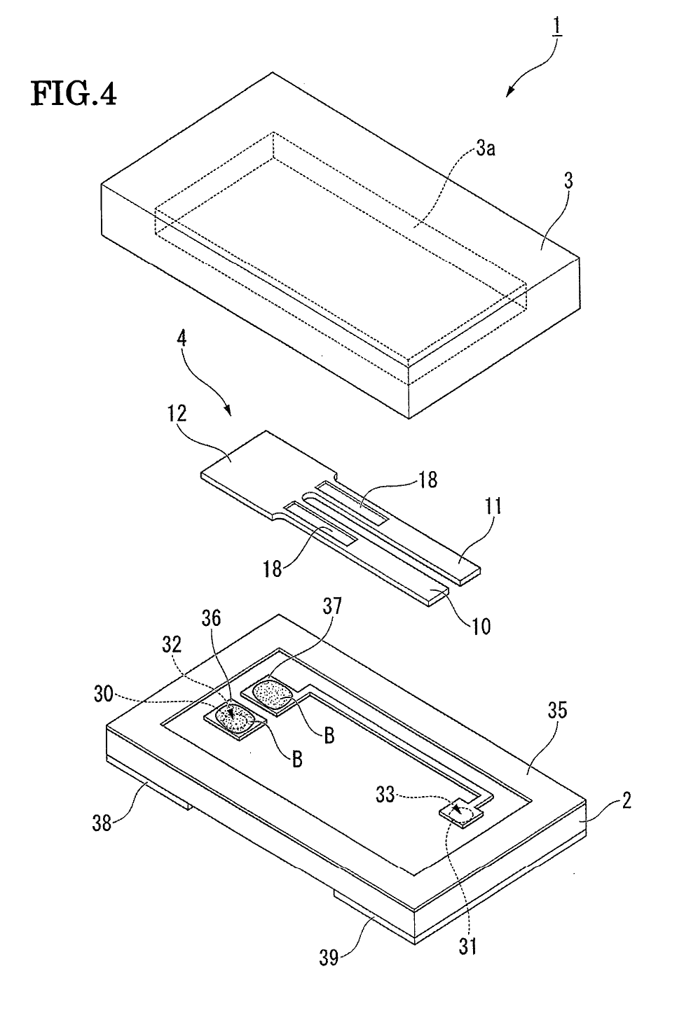

As shown in FIGS. 1 to 4, a piezoelectric vibrator 1 according to the present embodiment is a surface mounted device-type piezoelectric vibrator which is formed in the form of a box laminated in two layers of a base substrate 2 and a lid substrate 3 and in which a piezoelectric vibrating reed 4 is accommodated in a cavity C at an inner portion thereof. In FIG. 4, for better understanding of the drawings, illustrations of the excitation electrode 15, extraction electrodes 19 and 20, mount electrodes 16 and 17, and weight metal film 21 are omitted.

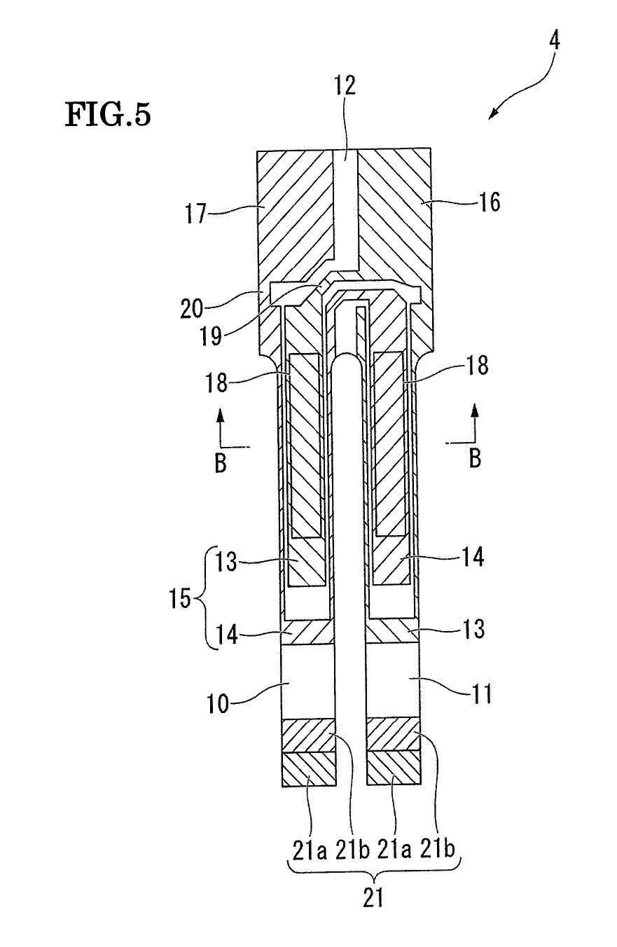

As shown in FIGS. 5 to 7, the piezoelectric vibrating reed 4 is a tuning-fork type vibrating reed which is made of a piezoelectric material such as crystal, lithium tantalate, or lithium niobate and is configured to vibrate when a predetermined voltage is applied thereto.

The piezoelectric vibrating reed 4 includes: a pair of vibrating arms 10 and 11 disposed in parallel to each other; a base portion 12 to which the base end sides of the pair of vibrating arms 10 and 11 are integrally fixed; an excitation electrode 15 which is formed on the outer surfaces of the pair of vibrating arms 10 and 11 so as to allow the pair of vibrating arms 10 and 11 to vibrate and includes a first excitation electrode 13 and a second excitation electrode 14; and mount electrodes 16 and 17 which are electrically connected to the first excitation electrode 13 and the second excitation electrode 14, respectively.

In addition, the piezoelectric vibrating reed 4 according to the present embodiment is provided with grooves 18 which are formed on both principal surfaces of the pair of vibrating arms 10 and 11 along the longitudinal direction of the vibrating arms 10 and 11. The grooves 18 are formed so as to extend from the base end sides of the vibrating arms 10 and 11 up to approximately the middle portions thereof.

The excitation electrode 15 including the first excitation electrode 13 and the second excitation electrode 14 is an electrode that allows the pair of vibrating arms 10 and 11 to vibrate at a predetermined resonance frequency in a direction moving closer to or away from each other and is patterned on the outer surfaces of the pair of vibrating arms 10 and 11 in an electrically isolated state. Specifically, the first excitation electrode 13 is mainly formed on the groove 18 of one vibrating arm 10 and both side surfaces of the other vibrating arm 11. On the other hand, the second excitation electrode 14 is mainly formed on both side surfaces of one vibrating arm 10 and the groove 18 of the other vibrating arm 11.

Moreover, the first excitation electrode 13 and the second excitation electrode 14 are electrically connected to the mount electrodes 16 and 17 via the extraction electrodes 19 and 20, respectively, on both principal surfaces of the base portion 12. Moreover, a voltage is applied to the piezoelectric vibrating reed 4 via the mount electrodes 16 and 17.

In addition, the excitation electrode 15, mount electrodes 16 and 17, and extraction electrodes 19 and 20 are formed, for example, by a coating of a conductive film formed of, chromium (Cr), nickel (Ni), aluminum (Al), titanium (Ti) or the like.

The tip ends of the pair of the vibrating arms 10 and 11 are coated with a weight metal film 21 for performing adjustment (frequency adjustment) of their vibration states in such a manner as to vibrate within a predetermined frequency range. In addition, the weight metal film 21 is divided into a rough tuning film 21a used for tuning the frequency roughly and a fine tuning film 21b used for tuning the frequency finely. By tuning the frequency with the use of the rough tuning film 21a and the fine tuning film 21b, the frequency of the pair of the vibrating arms 10 and 11 can be set to fall within the range of the nominal (target) frequency of the device.

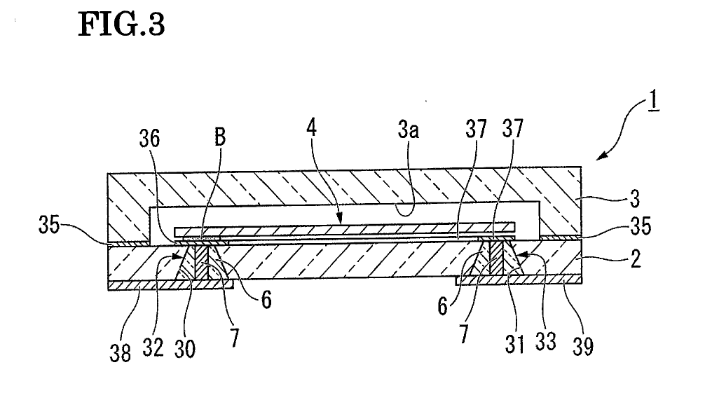

The piezoelectric vibrating reed 4 configured in this way is bump-bonded to the upper surface of the base substrate 2 through bumps B made of gold or the like as shown in FIGS. 3 and 4. More specifically, bump bonding is achieved in a state where the pair of mount electrodes 16 and 17 comes into contact with two bumps B, respectively, formed on lead-out electrodes 36 and 37 described later, which are patterned on the upper surface of the base substrate 2. In this way, the piezoelectric vibrating reed 4 is supported in a state of being floated from the upper surface of the base substrate 2, and the mount electrodes 16 and 17 and the lead-out electrodes 36 and 37 are electrically connected to each other.

The lid substrate 3 is a transparent insulating substrate made of a glass material, for example, soda-lime glass, and is formed in a plate-like shape as shown in FIGS. 1, 3, and 4. Moreover, a bonding surface side thereof to be bonded to the base substrate 2 is formed with a rectangular recess 3a in which the piezoelectric vibrating reed 4 is accommodated.

The recess 3a is a cavity recess serving as the cavity C that accommodates the piezoelectric vibrating reed 4 when the two substrates 2 and 3 are superimposed on each other. Moreover, the lid substrate 3 is anodically bonded to the base substrate 2 in a state where the recess 3a faces the base substrate 2.

The base substrate 2 is a transparent insulating substrate made of a glass material, for example, soda-lime glass, similarly to the lid substrate 3, and is formed in a plate-like shape having a size capable of being superimposed on the lid substrate 3, as shown in FIGS. 1 to 4.

The base substrate 2 is formed with a pair of through holes (penetration holes) 30 and 31 penetrating through the base substrate 2. In this case, the pair of through holes 30 and 31 is formed so as to be received in the cavity C. More specifically, the through holes 30 and 31 of the present embodiment are formed such that one through hole 30 is positioned close to the base portion 12 of the mounted piezoelectric vibrating reed 4, and the other through hole 31 is positioned at a corresponding position close to the tip end sides of the vibrating arms 10 and 11. The present embodiment is described by way of an example of the through holes which have a tapered sectional shape whose diameter gradually decreases from the lower surface of the base substrate 2 towards the upper surface. However, the invention is not limited to this example, and the through holes may be configured to penetrate straight through the base substrate 2. In any case, they only need to penetrate through the base substrate 2.

The pair of through holes 30 and 31 is formed with a pair of penetration electrodes 32 and 33 which are formed so as to be embedded in the through holes 30 and 31. As shown in FIG. 3, the penetration electrodes 32 and 33 are formed by a cylindrical member 6 and a core portion 7 which are integrally fixed to the through holes 30 and 31 by baking. The penetration electrodes 32 and 33 serve to maintain airtightness in the cavity C by completely blocking the through holes 30 and 31 and achieve electrical connection between the external electrodes 38 and 39 described later and the lead-out electrodes 36 and 37.

As shown in FIG. 8, the cylindrical member 6 is obtained by baking a paste-like glass frit 6a. The cylindrical member 6 has a cylindrical shape in which both ends are flat and which has approximately the same thickness as the base substrate 2. A core portion 7 is disposed at the center of the cylindrical member 6 so as to penetrate through the cylindrical member 6. In the present embodiment, the cylindrical member 6 has an approximately conical outer shape (a tapered sectional shape) so as to comply with the shapes of the through holes 30 and 31. As shown in FIG. 3, the cylindrical member 6 is baked in a state of being embedded in the through holes 30 and 31 and is tightly attached to the through holes 30 and 31.

The core portion 7 is a conductive cylindrical core material made of metallic material, and similarly to the cylindrical member 6, has a shape which has flat ends and approximately the same thickness as the base substrate 2. As shown in FIG. 3, when the penetration electrodes 32 and 33 are formed as a finished product, the core portion 7 has approximately the same thickness as the base substrate 2 as described above. However, in the course of the manufacturing process, the length of the core portion 7 being used is smaller by 0.02 mm than the thickness of the base substrate 2 in the initial state of the manufacturing process (which will be described later when describing the manufacturing method). Moreover, the core portion 7 is positioned at a central hole 6c of the cylindrical member 6, and is tightly attached to the cylindrical member 6 by the baking of the cylindrical member 6.

The electrical connection of the penetration electrodes 32 and 33 is secured via the conductive core portion 7.

As shown in FIGS. 1 to 4, the upper surface side of the base substrate 2 (the bonding surface side to be bonded to the lid substrate 3) is patterned with a bonding film 35 for anodic bonding and the pair of lead-out electrodes 36 and 37 by a conductive material (for example, aluminum). Among them, the bonding film 35 is formed along the peripheral edge of the base substrate 2 so as to surround the periphery of the recess 3a formed on the lid substrate 3.

Moreover, the pair of lead-out electrodes 36 and 37 are patterned so that one penetration electrode 32 of the pair of penetration electrodes 32 and 33 is electrically connected to one mount electrode 16 of the piezoelectric vibrating reed 4, and the other penetration electrode 33 is electrically connected to the other mount electrode 17 of the piezoelectric vibrating reed 4.

More specifically, one lead-out electrode 36 is formed right above the one penetration electrode 32 to be disposed right below the base portion 12 of the piezoelectric vibrating reed 4. Moreover, the other lead-out electrode 37 is formed to be disposed right above the other penetration electrode 33 after being led out from a position near the one lead-out electrode 36 towards the tip ends of the vibrating arms 10 and 11 along the vibrating arms 10 and 11.

The bumps B are formed on the pair of lead-out electrodes 36 and 37, and the piezoelectric vibrating reed 4 is mounted via the bumps B. In this way, the one mount electrode 16 of the piezoelectric vibrating reed 4 is electrically connected to the one penetration electrode 32 via the one lead-out electrode 36, and the other mount electrode 17 is electrically connected to the other penetration electrode 33 via the other lead-out electrode 37.

Moreover, the lower surface of the base substrate 2 is formed with the external electrodes 38 and 39 which are electrically connected to the pair of penetration electrodes 32 and 33, respectively, as shown in FIGS. 1, 3, and 4. That is, one external electrode 38 is electrically connected to the first excitation electrode 13 of the piezoelectric vibrating reed 4 via the one penetration electrode 32 and the one lead-out electrode 36. In addition, the other external electrode 39 is electrically connected to the second excitation electrode 14 of the piezoelectric vibrating reed 4 via the other penetration electrode 33 and the other lead-out electrode 37.

When the piezoelectric vibrator 1 configured in this manner is operated, a predetermined driving voltage is applied between the pair of external electrodes 38 and 39 formed on the base substrate 2. In this way, a current can be made to flow to the excitation electrode 15 including the first and second excitation electrodes 13 and 14, of the piezoelectric vibrating reed 4, and the pair of vibrating arms 10 and 11 is allowed to vibrate at a predetermined frequency in a direction moving closer to or away from each other. This vibration of the pair of vibrating arms 10 and 11 can be used as the time source, the timing source of a control signal, the reference signal source, and the like.

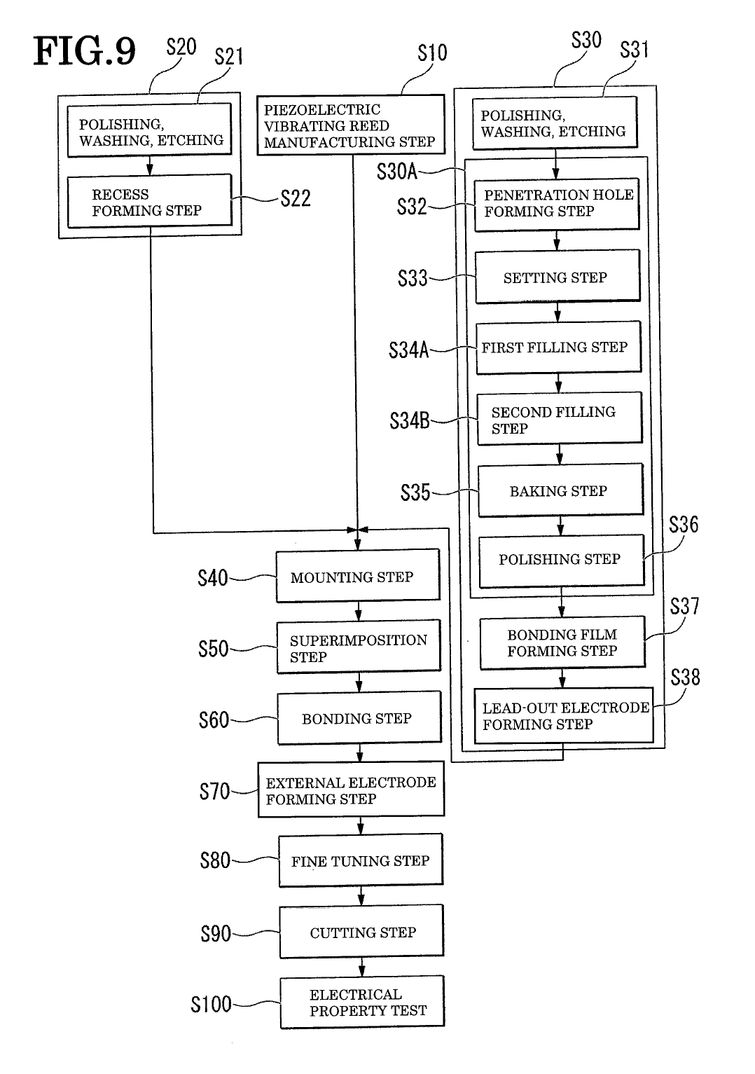

Next, a method of manufacturing a plurality of the above-described piezoelectric vibrators 1 at once using a base substrate wafer 40 and a lid substrate wafer 50 will be described with reference to the flowchart shown in FIG. 9.

First, a piezoelectric vibrating reed manufacturing step is performed to manufacture the piezoelectric vibrating reed 4 shown in FIGS. 5 to 7 (S10). Specifically, first, a Lambert ore made of crystal is sliced at a predetermined angle to obtain a wafer having a constant thickness. Subsequently, the wafer is subjected to crude processing by lapping, and an affected layer is removed by etching. Then, the wafer is subjected to mirror processing such as polishing to obtain a wafer having a predetermined thickness. Subsequently, the wafer is subjected to appropriate processing such as washing, and the wafer is patterned so as to have the outer shape of the piezoelectric vibrating reed 4 by a photolithography technique. Moreover, a metal film is formed and patterned on the wafer, thus forming the excitation electrode 15, the extraction electrodes 19 and 20, the mount electrodes 16 and 17, and the weight metal film 21. In this way, a plurality of piezoelectric vibrating reeds 4 can be manufactured.

Moreover, after the piezoelectric vibrating reed 4 is manufactured, rough tuning of a resonance frequency is performed. This rough tuning is achieved by irradiating the rough tuning film 21a of the weight metal film 21 with a laser beam to partially evaporate the rough tuning film 21a, thus changing the weight thereof. In addition, fine tuning of adjusting the resonance frequency more accurately is performed after a mounting step is performed. This will be described later.

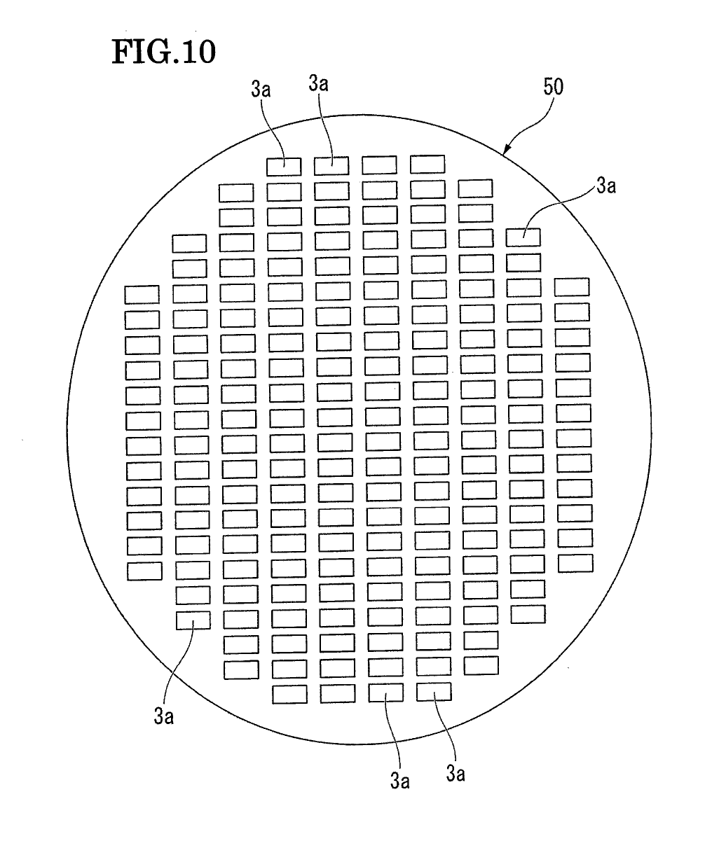

Subsequently, a first wafer manufacturing step is performed where the lid substrate wafer 50 later serving as the lid substrate 3 is manufactured up to the stage immediately before anodic bonding is achieved (S20). First, a disk-shaped lid substrate wafer 50 is formed by polishing a piece of soda-lime glass to a predetermined thickness, washing the polished glass, and removing the affected uppermost layer by etching or the like (S21) as shown in FIG. 10. Subsequently, a recess forming step is performed where a plurality of cavity recesses 3a is formed in a matrix form on the bonding surface of the lid substrate wafer 50 by etching or the like (S22). At this point in time, the first wafer manufacturing step ends.

Subsequently, at the same or a different time as the first wafer manufacturing step, a second wafer manufacturing step is performed where a base substrate wafer 40 later serving as the base substrate 2 is manufactured up to the stage immediately before anodic bonding is achieved (S30). First, a disk-shaped base substrate wafer 40 is formed by polishing a piece of soda-lime glass to a predetermined thickness, washing the polished glass, and removing the affected uppermost layer by etching or the like (S31). Subsequently, a penetration electrode forming step is performed where a plurality of pairs of penetration electrodes 32 and 33 is formed on the base substrate wafer 40 (S30A). Here, the penetration electrode forming step will be described in detail below.

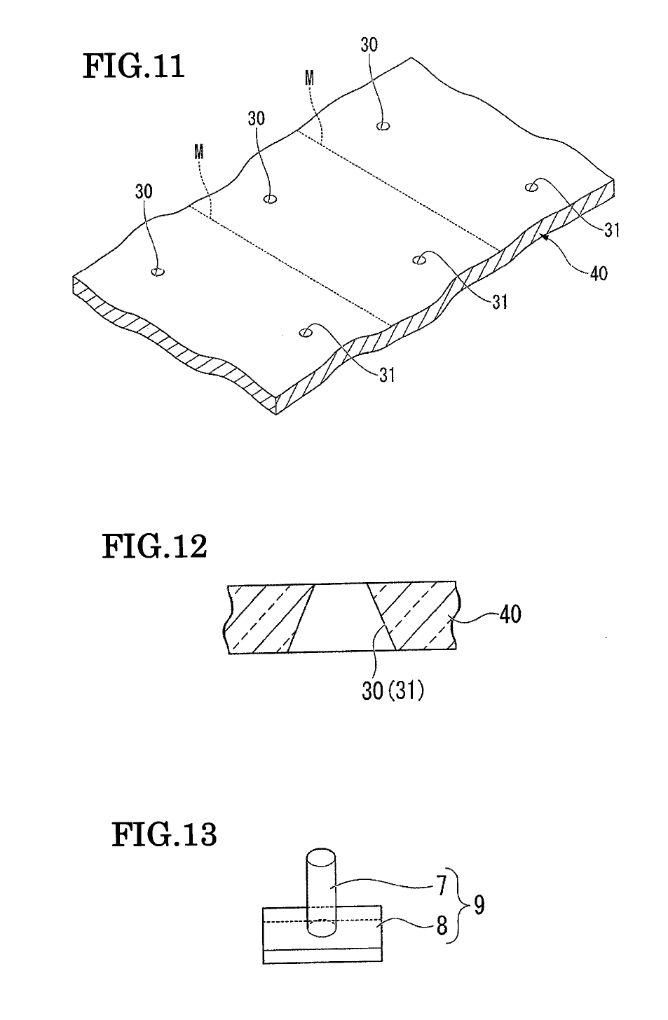

First, as shown in FIG. 11, a penetration hole forming step is performed where a plurality of pairs of through holes 30 and 31 is formed so as to penetrate through the base substrate wafer 40 (S32). The dotted line M shown in FIG. 11 is a cutting line along which a cutting step performed later occurs. When this step is performed, the through holes are formed from the lower surface of the base substrate wafer 40, for example, using a sand blast method. In this way, as shown in FIG. 12, the through holes 30 and 31 having a tapered sectional shape in which the diameter gradually decreases from the lower surface of the base substrate wafer 40 towards the upper surface can be formed. Moreover, a plurality of pairs of through holes 30 and 31 is formed so as to be received in the recesses 3a formed on the lid substrate wafer 50 when the two wafers 40 and 50 are superimposed on each other later. In addition, the through holes are formed so that one through hole 30 is positioned close to the base portion 12 of the piezoelectric vibrating reed 4, and the other through hole 31 is positioned close to the tip end side of the vibrating arms 10 and 11.

Subsequently, a setting step is performed where the core portions 7 of the rivet members 9 are disposed in the plurality of through holes 30 and 31. At that time, as shown in FIG. 13, as the rivet member 9, a conductive rivet member 9 which has a planar base portion 8 and a core portion 7 which extends upwardly from the base portion 8 in a direction approximately perpendicular to the surface of the base portion 8 and has a length slightly shorter, for example, by about 0.02 mm than the thickness of the base substrate wafer 40 and a flat tip end is used.

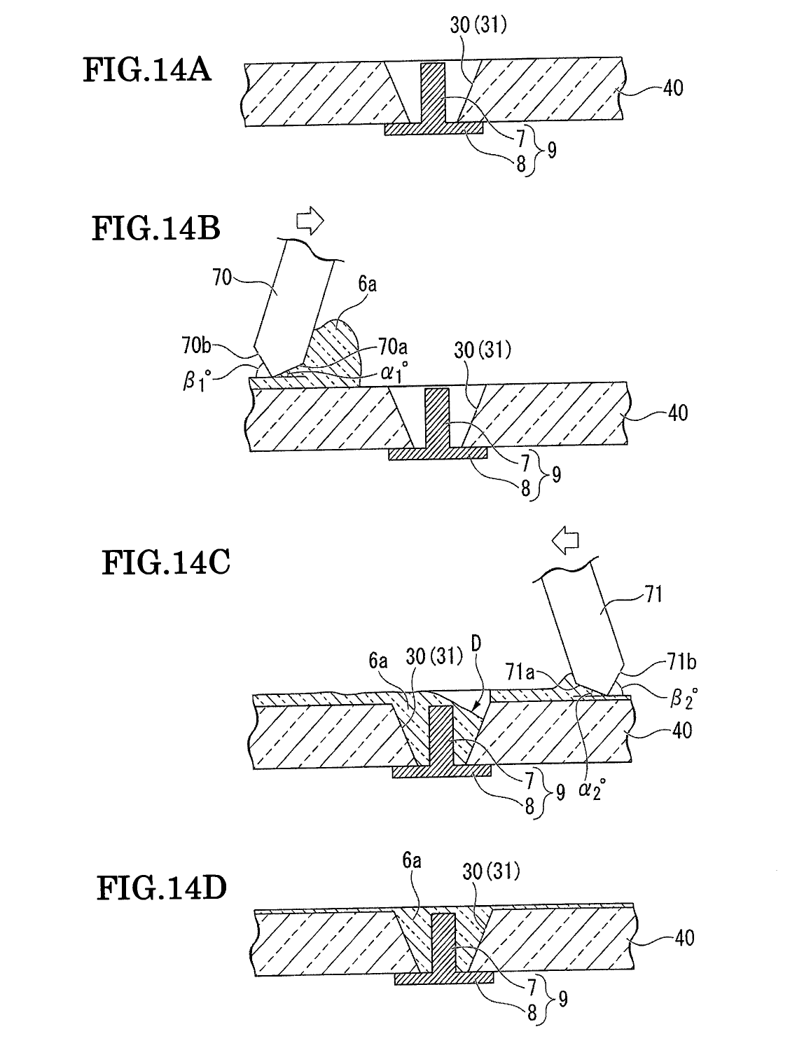

In this setting step, as shown in FIG. 14A, the core portion 7 is inserted until the base portion 8 of the rivet member 9 comes into contact with the base substrate wafer 40. Here, it is necessary to dispose the rivet member 9 so that the axial direction of the core portion 7 is approximately identical to the axial direction of the through holes 30 and 31. In the present embodiment, since the rivet member 9 having the core portion 7 formed on the base portion 8 is used, it is possible to make the axial direction of the core portion 7 identical to the axial direction of the through holes 30 and 31 by a simple operation of pushing the rivet member 9 until the base portion 8 comes into contact with the base substrate wafer 40. Therefore, it is possible to improve workability during the setting step.

Furthermore, by bringing the base portion 8 into contact with the surface of the base substrate wafer 40, since the openings on one side of the through holes 30 and 31 can be blocked, it is possible to easily fill the paste-like glass frit 6a into the through holes 30 and 31. Moreover, since the base portion 8 has a planar shape, the base substrate wafer 40 can be placed stably on a flat surface of a desk or the like without any rattling during the period between the setting step and the baking step performed later. In this respect, it is also possible to improve the workability.

Then, a first filling step is performed where the paste-like glass frit 6a made of a glass material is filled in the through holes 30 and 31 (S34A). In the first filling step, as shown in FIG. 14B, the glass frit 6a is applied on the surface (second surface) of the base substrate wafer 40, and a first squeegee 70 is moved in a state where it comes into contact with the surface of the base substrate wafer 40, thereby filling the glass frit 6a into the through holes 30 and 31.

The first squeegee 70 has a rod-like or plate-like shape extending approximately in the vertical direction and has an attack surface 70a and an escape surface 70b which are formed on the lower tip end thereof. The attack surface 70a is inclined at a predetermined attack angle α₁° with respect to the surface of the base substrate wafer 40 and comes into contact with the surface. The escape surface 70b is inclined at a predetermined escape angle β₁° with respect to the surface of the base substrate wafer 40 and extends from the contact portion between the attack surface 70a and the surface of the base substrate wafer 40.

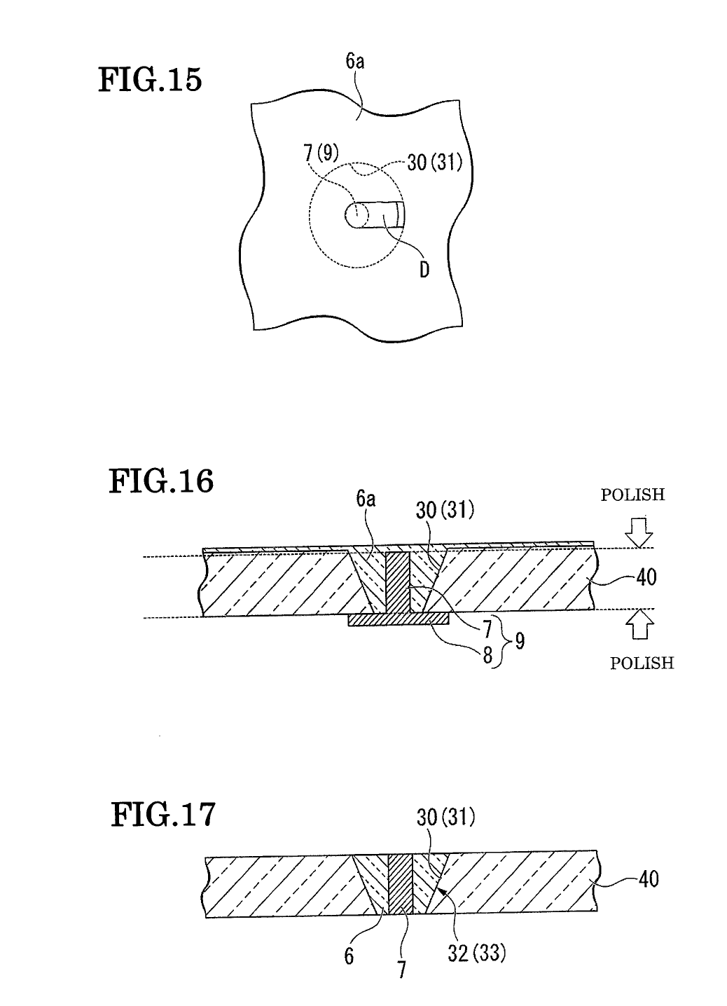

Moreover, in the first filling step S34A, as shown in FIG. 14B, the first squeegee 70 is moved along the surface of the base substrate wafer 40 in a state where the attack surface 70a of the first squeegee 70 faces the front side in the movement direction and comes into contact with the surface of the base substrate wafer 40. In this way, as shown in FIG. 14C, most of the glass frit 6a applied on the surface of the base substrate wafer 40 is filled in the through holes 30 and 31. Moreover, in this case, in portions of the through holes 30 and 31 on the back surface side of the core portion 7 in the movement direction of the first squeegee 70, there is a case in which the glass frit 6a is not filled up to the upper portions of the openings of the through holes 30 and 31, but depressions D are formed as shown in FIGS. 14C and 15. Thus, if baking is performed in a state where the depressions D are formed in the glass frit 6a, there is a problem in that a step is formed in the through holes 30 and 31, and the airtightness in the cavity C or the electrical connection between the electrodes is impaired. In this respect, in the present embodiment, the above problem is eliminated by performing a second filling step (S34B) described later.

The second filling step (S34B) is performed by moving a second squeegee 71 in the opposite direction to the movement direction of the first squeegee 70 in a state where the second squeegee 71 comes into contact with the surface of the base substrate wafer 40.

The second squeegee 71 has a rod-like or plate-like shape extending approximately in the vertical direction and has an attack surface 71a and an escape surface 71b which are formed on the lower tip end thereof. The attack surface 71a is inclined at a predetermined attack angle α₂° with respect to the surface of the base substrate wafer 40 and comes into contact with the surface. The escape surface 71b is inclined at a predetermined escape angle β₂° with respect to the surface of the base substrate wafer 40 and extends from the contact portion between the attack surface 71a and the surface of the base substrate wafer 40.

Moreover, in the second filling step (S34B), as shown in FIG. 14C, the second squeegee 71 is moved along the surface of the base substrate wafer 40 in a state where the attack surface 71a of the second squeegee 71 faces the front side in the movement direction and comes into contact with the surface of the base substrate wafer 40. The movement direction of the second squeegee 71 is opposite to the movement direction of the first squeegee 70.

Through such a movement of the second squeegee 71, as shown in FIG. 14C, the glass frit 6a which is not filled in the through holes 30 and 31 by the movement of the first squeegee 70 but remains on the surface of the base substrate wafer 40 is removed from the surface and filled in the through holes 30 and 31, specifically, in the depressions D in the through holes 30 and 31.

In addition, in the present embodiment, the length of the core portion 7 of the rivet member 9 is smaller by a distance of 0.02 mm than the thickness of the base substrate wafer 40. Therefore, when the first squeegee 70 or the second squeegee 71 passes over the upper portions of the through holes 30 and 31 in the first filling step (S34A) and the second filling step (S34B), the first squeegee 70 and the second squeegee 71 will not make contact with the tip end of the core portion 7. Thus, it is possible to prevent the core portion 7 from being tilted.

In this way, by performing the filling operation in two steps using the first squeegee 70 and the second squeegee 71, the depressions D in the through holes 30 and 31 are buried, and the through holes 30 and 31 are filled with the glass frit 6a. Therefore, no step will be formed in the through holes 30 and 31 after the baking described later is performed, and it is possible to secure stable electrical connection between the piezoelectric vibrating reed 4 and the external electrodes 38 and 39 in the cavity C.

Here, the attack angles α₁ and α₂ of the first squeegee 70 and the second squeegee 71 are preferably set to be within the range of 5° to 45°. If the attack angles α₁ and α₂ exceed 45°, although the performance of removing the glass frit 6a from the surface of the base substrate wafer 40 improves, the performance of filling the glass frit 6a in the through holes 30 and 31 deteriorates, and this is not desirable. Moreover, if the attack angles α₁ and α₂ are smaller than 5°, the resistance when moving the first and second squeegees 70 and 71 increases, and it is not possible to perform the first filling step S34A and the second filling step S34B smoothly. In this respect, since the attack angles α₁ and α₂ are set to be within the range of 5° to 45°, it is possible to suppress the resistance when moving the first and second squeegees 70 and 71 while effectively filling the glass frit 6a in the through holes 30 and 31 and to perform the filling operation in a smooth and easy manner.

Moreover, since the escape surfaces 70b and 71b having the predetermined escape angles β₁ and β₂ are formed on the first and second squeegees 70 and 71, respectively, it is possible to further decrease the resistance when moving the first and second squeegees 70 and 71 and to perform the filling operation more smoothly.

In addition, it is preferable that the attack angles α₁ and α₂ and the escape angles β₁ and β₂ are set to 15° and 65°, respectively. In this case, it is possible to fill the glass frit 6a in the through holes 30 and 31 efficiently while decreasing the movement resistance of the first and second squeegees 70 and 71 to the largest extent.

Moreover, the attack angles α₁ and α₂ and the escape angles β₁ and β₂ of the first and second squeegees 70 or 71 may be set to the same values and may be set to different values. When these angles are set to the same values, the first and second squeegees 70 and 71 can be configured as the same squeegee, and it is thus preferable from the perspective of cost.

Thus, in a state where the filling operation of the two steps of the first and second filling steps (S34A and S34B) is completed, although the inside of the through holes 30 and 31 is completely filled with the glass frit 6a, as shown in FIG. 14D, the glass frit 6a on the surface of the base substrate wafer 40 is not completely removed but slightly remains thereon. In this respect, since the glass frit 6a on the surface is removed through a polishing step after baking, it is not necessary to perform an additional step of removing the glass frit 6a after the first and second filling steps (S34A and S34B).

Subsequently, a baking step is performed where the embedded filling material is baked at a predetermined temperature (S35). In this way, the through holes 30 and 31, the glass frit 6a embedded in the through holes 30 and 31, and the rivet members 9 disposed in the glass frit 6a are attached to each other. During this step, since the baking is performed for each base portion 8, the through holes 30 and 31 and the rivet members 9 can be integrally fixed to each other in a state where the axial direction of the core portion 7 is approximately identical to the axial direction of the through holes 30 and 31. When the glass frit 6a is baked, it is solidified as the cylindrical members 6.

Subsequently, as shown in FIG. 16, after the baking, a polishing step is performed so as to polish and remove the base portions 8 of the rivet members 9 (S35). In this way, it is possible to remove the base portions 8 that serve to align the cylindrical members 6 and the core portions 7, and to allow only the core portions 7 to remain in the cylindrical members 6.

Moreover, at the same time, the rear surface (the surface where the base portion 8 of the rivet member 9 is not disposed) of the base substrate wafer 40 is polished to obtain a flat surface. The polishing is continued until the tip end of the core portion 7 is exposed. As a result, as shown in FIG. 17, it is possible to obtain a plurality of pairs of penetration electrodes 32 and 33 in which the cylindrical member 6 and the core portion 7 are integrally fixed.

In addition, when forming the penetration electrodes 32 and 33, unlike the prior art, a paste is not used for the conductive member, and the penetration electrodes 32 and 33 are formed using the cylindrical member 6 made of a glass material and the conductive core portion 7. If a paste is used for the conductive member, since organic materials included in the paste will be evaporated during baking, the volume of the paste will decrease greatly as compared to the volume before baking. Therefore, if only the paste is embedded in the through holes 30 and 31, large depressions will be formed on the surface of the paste after baking. However, in the present embodiment, since the core portion 7 made of metal is used for the conductive member, it is possible to prevent a decrease in the volume of the conductive member.

As described above, the surfaces of the base substrate wafer 40 are approximately flush with both ends of the cylindrical member 6 and the core portion 7. That is, it is possible to make the surfaces of the base substrate wafer 40 approximately flush with the surfaces of the penetration electrodes 32 and 33. The penetration electrode forming step ends at the time when the polishing step is performed.

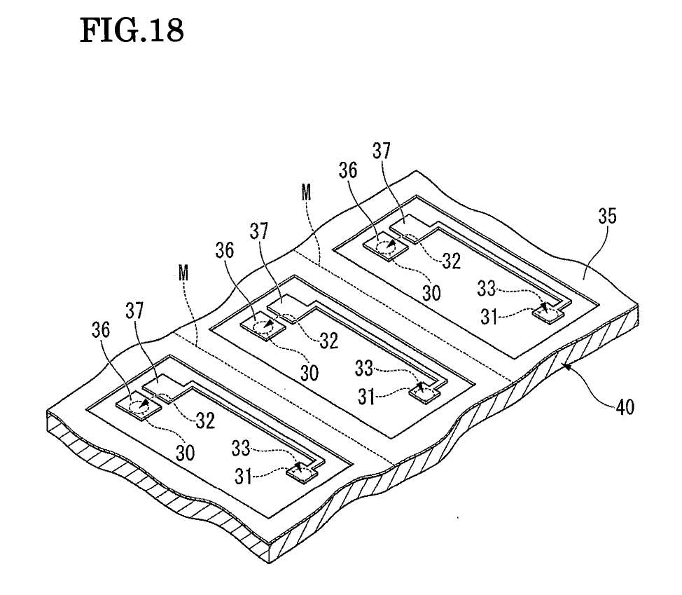

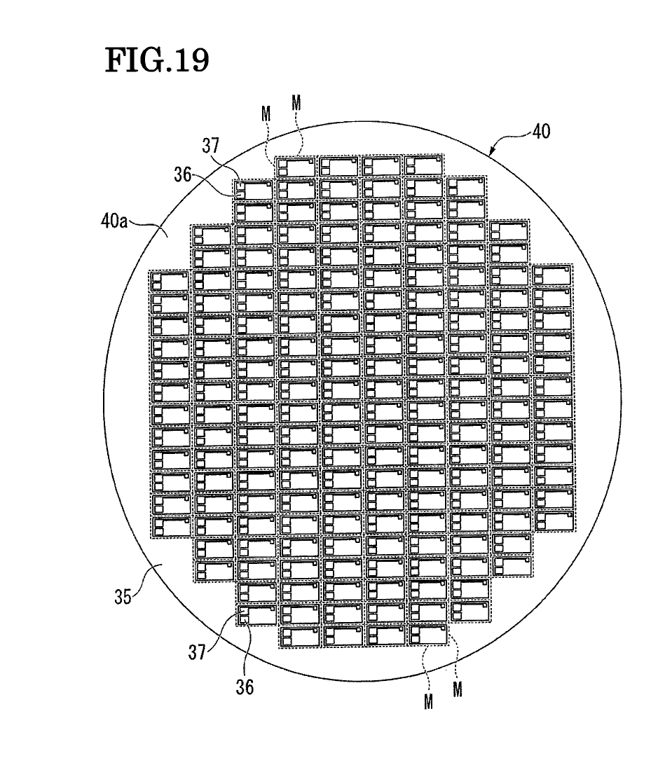

Subsequently, a bonding film forming step is performed where a conductive material is patterned on the upper surface of the base substrate wafer 40 so as to form a bonding film 35 as shown in FIGS. 18 and 19 (S37). Moreover, a lead-out electrode forming step is performed where a plurality of lead-out electrodes 36 and 37 is formed so as to be electrically connected to each pair of penetration electrodes 32 and 33, respectively (S38). The dotted line M shown in FIGS. 18 and 19 is a cutting line along which a cutting step performed later occurs.

Particularly, as described above, the penetration electrodes 32 and 33 are approximately flush with the upper surface of the base substrate wafer 40. Therefore, the lead-out electrodes 36 and 37 which are patterned on the upper surface of the base substrate wafer 40 are closely adhered onto the penetration electrodes 32 and 33 without forming any gap or the like therebetween. In this way, it is possible to achieve reliable electrical connection between the one lead-out electrode 36 and the one penetration electrode 32 and reliable electrical connection between the other lead-out electrode 37 and the other penetration electrode 33. At this point in time, the second wafer manufacturing step ends.

In FIG. 9, although the lead-out electrode forming step (S38) is performed after the bonding film forming step (S37), conversely, the bonding film forming step (S37) may be performed after the lead-out electrode forming step (S38), and the two steps may be performed at the same time. The same operational effect can be obtained with any order of the steps. Therefore, the order of the steps may be appropriately changed as necessary.

Subsequently, a mounting step is performed where a plurality of manufactured piezoelectric vibrating reeds 4 is bonded to the upper surface of the base substrate wafer 40 with the lead-out electrodes 36 and 37 disposed therebetween (S40). First, bumps B made of gold or the like are formed on the pair of lead-out electrodes 36 and 37. The base portion 12 of the piezoelectric vibrating reed 4 is placed on the bumps B, and thereafter the piezoelectric vibrating reed 4 is pressed against the bumps B while heating the bumps B to a predetermined temperature. In this way, the piezoelectric vibrating reed 4 is mechanically supported by the bumps B, and the mount electrodes 16 and 17 are electrically connected to the lead-out electrodes 36 and 37. Therefore, at this point in time, the pair of excitation electrodes 15 of the piezoelectric vibrating reed 4 is electrically connected to the pair of penetration electrodes 32 and 33, respectively.

Particularly, since the piezoelectric vibrating reed 4 is bump-bonded, the piezoelectric vibrating reed 4 is supported in a state of being floated from the upper surface of the base substrate wafer 40.

After the piezoelectric vibrating reed 4 is mounted, a superimposition step is performed where the lid substrate wafer 50 is superimposed on the base substrate wafer 40 (S50). Specifically, both wafers 40 and 50 are aligned at a correct position using reference marks or the like not shown in the drawing as indices. In this way, the mounted piezoelectric vibrating reed 4 is accommodated in the recess 3a formed on the base substrate wafer 40, and in the cavity C which is surrounded by the two wafers 40 and 50.

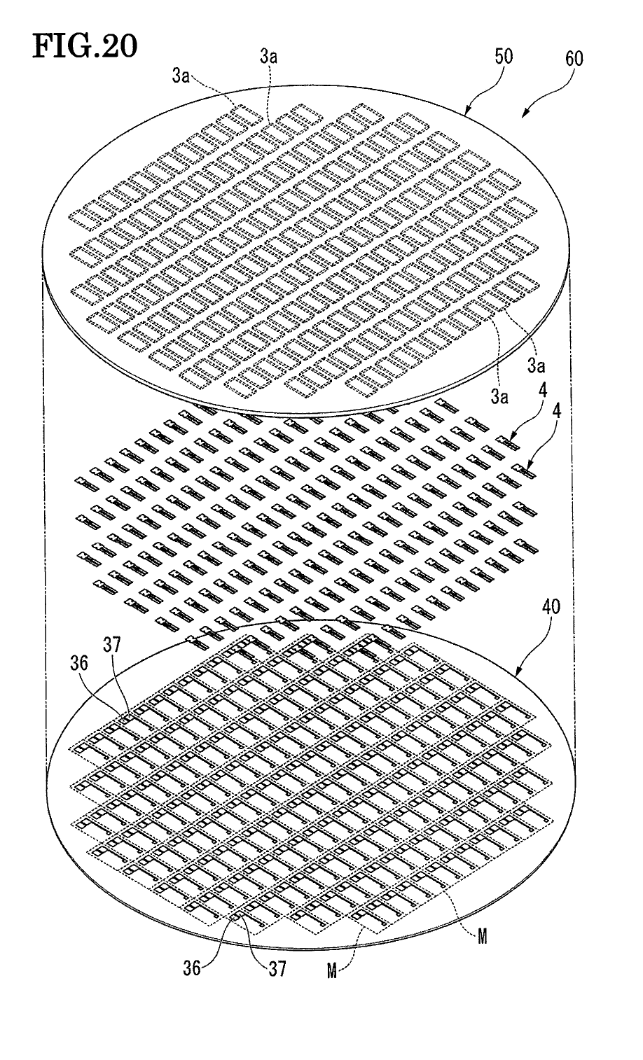

After the superimposition step is performed, a bonding step is performed where the two superimposed wafers 40 and 50 are inserted into an anodic bonding machine (not shown) to achieve anodic bonding under a predetermined temperature atmosphere with application of a predetermined voltage (S60). Specifically, a predetermined voltage is applied between the bonding film 35 and the lid substrate wafer 50. Then, an electrochemical reaction occurs at the interface between the bonding film 35 and the lid substrate wafer 50, whereby they are strengthened and tightly adhered and anodically bonded, respectively. In this way, the piezoelectric vibrating reed 4 can be sealed in the cavity C, and a wafer assembly 60 shown in FIG. 20 can be obtained in which the base substrate wafer 40 and the lid substrate wafer 50 are bonded to each other. In FIG. 20, for better understanding of the drawing, the wafer assembly 60 is illustrated in an exploded state, and illustration of the bonding film 35 is omitted from the base substrate wafer 40. The dotted line M shown in FIG. 20 is a cutting line along which a cutting step performed later occurs.

When the anodic bonding is performed, since the through holes 30 and 31 formed on the base substrate wafer 40 are completely blocked by the penetration electrodes 32 and 33, the airtightness in the cavity C will not be impaired by the through holes 30 and 31. Particularly, since the cylindrical member 6 and the core portion 7 are integrally fixed by the baking, and they are tightly attached to the through holes 30 and 31, it is possible to reliably maintain airtightness in the cavity C.

After the above-described anodic bonding is completed, an external electrode forming step is performed where a conductive material is patterned onto the lower surface of the base substrate wafer 40 so as to form a plurality of pairs of external electrodes 38 and 39 which is electrically connected to the pair of penetration electrodes 32 and 33 (S70). Through this step, the piezoelectric vibrating reed 4 which is sealed in the cavity C can be operated using the external electrodes 38 and 39.

Particularly, when this step is performed, similarly to the step of forming the lead-out electrodes 36 and 37, since the penetration electrodes 32 and 33 are approximately flush with the lower surface of the base substrate wafer 40, the patterned external electrodes 38 and 39 are closely adhered onto the penetration electrodes 32 and 33 without forming any gap or the like therebetween. In this way, it is possible to achieve a reliable electrical connection between the external electrodes 38 and 39 and the penetration electrodes 32 and 33.

Subsequently, a fine tuning step is performed on the wafer assembly 60 where the frequencies of the individual piezoelectric vibrators 1 sealed in the cavities C are tuned finely to fall within a predetermined range (S80). Specifically, a voltage is applied to the pair of external electrodes 38 and 39 which are formed on the lower surface of the base substrate wafer 40, thus allowing the piezoelectric vibrating reeds 4 to vibrate. A laser beam is irradiated onto the lid substrate wafer 50 from the outer side while measuring the vibration frequencies to evaporate the fine tuning film 21b of the weight metal film 21. In this way, since the weight on the tip end sides of the pair of vibrating arms 10 and 11 is changed, the fine tuning can be performed in such a way that the frequency of the piezoelectric vibrating reed 4 falls within the predetermined range of the nominal frequency.

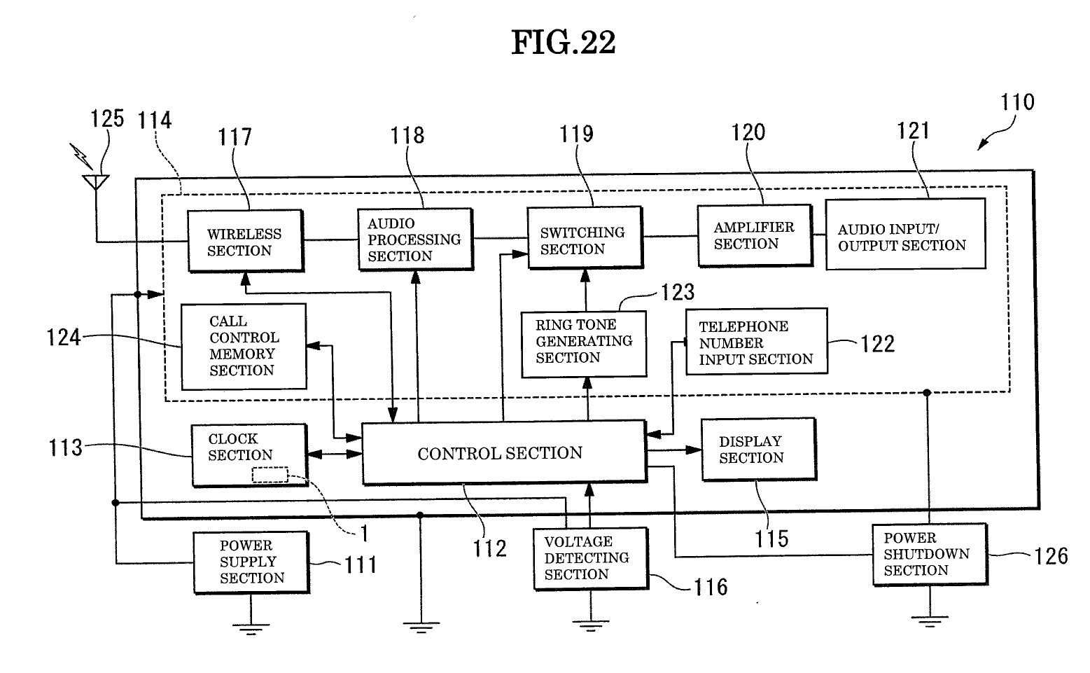

After the fine tuning of the frequency is completed, a cutting step is performed where the bonded wafer assembly 60 is cut along the cutting line M shown in FIG. 22 to obtain small fragments (S90). As a result, a plurality of two-layered surface mounted device-type piezoelectric vibrators 1 shown in FIG. 1, in which the piezoelectric vibrating reed 4 is sealed in the cavity C formed between the base substrate 2 and the lid substrate 3 being anodically bonded together, can be manufactured at once.

The fine tuning step (S80) may be performed after performing the cutting step (S90) to obtain the individual fragmented piezoelectric vibrators 1. However, as described above, by performing the fine tuning step (S80) earlier, since the fine tuning step can be performed on the wafer assembly 60, it is possible to perform the fine tuning on the plurality of piezoelectric vibrators 1 more efficiently. Therefore, it is desirable because throughput can be increased.

Subsequently, an internal electrical property test is conducted (S100). That is, the resonance frequency, resonance resistance value, drive level properties (the excitation power dependence of the resonance frequency and the resonance resistance value), and the like of the piezoelectric vibrating reed 4 are measured and checked. Moreover, the insulation resistance properties and the like are compared and checked as well. Finally, an external appearance test of the piezoelectric vibrator 1 is conducted to check the dimensions, the quality, and the like. In this way, the manufacturing of the piezoelectric vibrator 1 ends.

In particular, according to the piezoelectric vibrator 1 of the present embodiment, since the penetration electrodes 32 and 33 can be formed with no depression on the surface in a state of being approximately flush with the base substrate 2, the penetration electrodes 32 and 33 can be closely adhered securely to the lead-out electrodes 36 and 37 and the external electrodes 38 and 39. As a result, it is possible to secure stable electrical connection between the piezoelectric vibrating reed 4 and the external electrodes 38 and 39 and improve the reliability in operational performance to achieve higher performance. In addition, since the penetration electrodes 32 and 33 are formed by the conductive core portions 7, it is possible to obtain a very stable electrical connection.

In addition, since reliable airtightness in the cavity C can be maintained, in this respect, it is possible to achieve high quality. In particular, since the cylindrical member 6 of the present embodiment is formed by a material obtained by mixing glass beads in a glass frit, a deformation, a decrease in the volume, or the like barely occurs in the subsequent baking step. Therefore, it is possible to form the penetration electrode 32 and 33 having high quality and to secure more reliable airtightness in the cavity C. Accordingly, it is possible to improve the quality of the piezoelectric vibrator 1.

Moreover, according to the manufacturing method of the present embodiment, since a plurality of piezoelectric vibrators 1 can be manufactured at once, it is possible to achieve cost reduction.

Furthermore, in the present embodiment, when forming the penetration electrodes 32 and 33 on the base substrate wafer 40, since the filling operation is performed in two steps wherein after the glass frit 6a is filled in the penetration holes 30 and 31 using the first squeegee 70, the second squeegee 71 is moved in the opposite direction to the movement direction of the first squeegee 70 to thereby fill the glass frit 6a in the penetration holes, it is possible to securely fill the glass frit 6a in the through holes 30 and 31 and to prevent the occurrence of the depressions D. Therefore, since it is possible to obviate steps which cause cracks from being formed in the through holes 30 and 31 after baking, it is possible to secure the airtightness in the cavity C and stable electrical connection between the piezoelectric vibrating reed 4 and the external electrodes 38 and 39.

### (Oscillator)

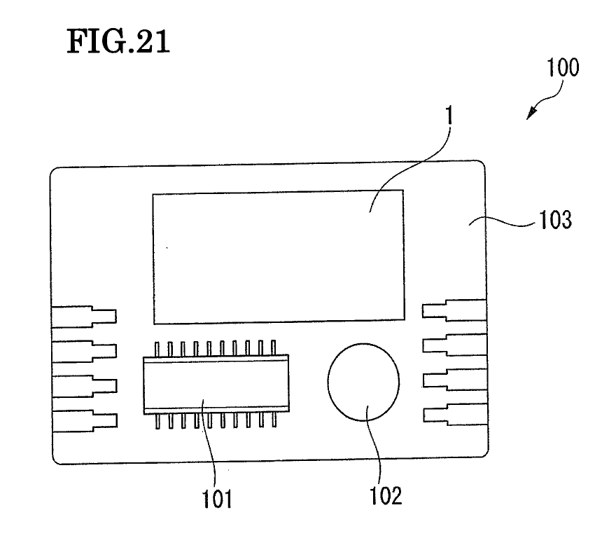

Next, an oscillator according to an embodiment of the invention will be described with reference to FIG. 21.

In an oscillator 100 according to the present embodiment, the piezoelectric vibrator 1 is used as an oscillating piece electrically connected to an integrated circuit 101, as shown in FIG. 21. The oscillator 100 includes a substrate 103 on which an electronic component 102, such as a capacitor, is mounted. The integrated circuit 101 for an oscillator is mounted on the substrate 103, and the piezoelectric vibrator 1 is mounted near the integrated circuit 101. The electronic component 102, the integrated circuit 101, and the piezoelectric vibrator 1 are electrically connected to each other by a wiring pattern (not shown). In addition, each of the constituent components is molded with a resin (not shown).

In the oscillator 100 configured as described above, when a voltage is applied to the piezoelectric vibrator 1, the piezoelectric vibrating reed 4 in the piezoelectric vibrator 1 vibrates. This vibration is converted into an electrical signal due to the piezoelectric property of the piezoelectric vibrating reed 4 and is then input to the integrated circuit 101 as the electrical signal. The input electrical signal is subjected to various kinds of processing by the integrated circuit 101 and is then output as a frequency signal. In this way, the piezoelectric vibrator 1 functions as an oscillating piece.

Moreover, by selectively setting the configuration of the integrated circuit 101, for example, an RTC (Real Time Clock) module, according to demand, it is possible to add a function of controlling the operation date or time of the corresponding device or an external device or of providing the time or calendar in addition to a single functional oscillator for a clock.

As described above, since the oscillator 100 according to the present embodiment includes the high-quality piezoelectric vibrator 1 in which the airtightness in the cavity C is secured, stable electrical connection between the piezoelectric vibrating reed 4 and the external electrodes 38 and 39 is secured, and operational reliability is improved, it is possible to achieve an improvement in the operational reliability and high quality of the oscillator 100 itself which provides stable electrical connection. In addition to this, it is possible to obtain a highly accurate frequency signal which is stable over a long period of time.

### (Electronic Device)

Next, an electronic device according to an embodiment of the invention will be described with reference to FIG. 22. In addition, a mobile information device 110 including the piezoelectric vibrator 1 as described above will be described as an example of an electronic device.

The mobile information device 110 according to the present embodiment is represented by a mobile phone, for example, and has been developed and improved from a wristwatch in the related art. The mobile information device 110 is similar to a wristwatch in external appearance, and a liquid crystal display is disposed in a portion equivalent to a dial pad so that the current time and the like can be displayed on this screen. Moreover, when it is used as a communication apparatus, it is possible to remove it from the wrist and to perform the same communication as a mobile phone in the related art with a speaker and a microphone built in an inner portion of the band. However, the mobile information device 110 is very small and light compared with a mobile phone in the related art.

Next, the configuration of the mobile information device 110 according to the present embodiment will be described. As shown in FIG. 22, the mobile information device 110 includes the piezoelectric vibrator 1 and a power supply section 111 for supplying power. The power supply section 111 is formed of a lithium secondary battery, for example. A control section 112 which performs various kinds of control, a clock section 113 which performs counting of time and the like, a communication section 114 which performs communication with the outside, a display section 115 which displays various kinds of information, and a voltage detecting section 116 which detects the voltage of each functional section are connected in parallel to the power supply section 111. In addition, the power supply section 111 supplies power to each functional section.

The control section 112 controls an operation of the entire system. For example, the control section 112 controls each functional section to transmit and receive the audio data or to measure or display a current time. In addition, the control section 112 includes a ROM in which a program is written in advance, a CPU which reads and executes a program written in the ROM, a RAM used as a work area of the CPU, and the like.

The clock section 113 includes an integrated circuit, which has an oscillation circuit, a register circuit, a counter circuit, and an interface circuit therein, and the piezoelectric vibrator 1. When a voltage is applied to the piezoelectric vibrator 1, the piezoelectric vibrating reed 4 vibrates, and this vibration is converted into an electrical signal due to the piezoelectric property of crystal and is then input to the oscillation circuit as the electrical signal. The output of the oscillation circuit is binarized to be counted by the register circuit and the counter circuit. Then, a signal is transmitted to or received from the control section 112 through the interface circuit, and current time, current date, calendar information, and the like are displayed on the display section 115.

The communication section 114 has the same function as a mobile phone in the related art, and includes a wireless section 117, an audio processing section 118, a switching section 119, an amplifier section 120, an audio input/output section 121, a telephone number input section 122, a ring tone generating section 123, and a call control memory section 124.

The wireless section 117 transmits/receives various kinds of data, such as audio data, to/from the base station through an antenna 125. The audio processing section 118 encodes and decodes an audio signal input from the wireless section 117 or the amplifier section 120. The amplifier section 120 amplifies a signal input from the audio processing section 118 or the audio input/output section 121 up to a predetermined level. The audio input/output section 121 is formed by a speaker, a microphone, and the like, and amplifies a ring tone or incoming sound or collects the sound.

In addition, the ring tone generating section 123 generates a ring tone in response to a call from the base station. The switching section 119 switches the amplifier section 120, which is connected to the audio processing section 118, to the ring tone generating section 123 only when a call arrives, so that the ring tone generated in the ring tone generating section 123 is output to the audio input/output section 121 through the amplifier section 120.

In addition, the call control memory section 124 stores a program related to incoming and outgoing call control for communications. Moreover, the telephone number input section 122 includes, for example, numeric keys from 0 to 9 and other keys. The user inputs a telephone number of a communication destination by pressing these numeric keys and the like.

The voltage detecting section 116 detects a voltage drop when a voltage, which is applied from the power supply section 111 to each functional section, such as the control section 112, drops below the predetermined value, and notifies the control section 112 of the detection of the voltage drop. In this case, the predetermined voltage value is a value which is set beforehand as the lowest voltage necessary to operate the communication section 114 stably. For example, it is about 3 V. When the voltage drop is notified from the voltage detecting section 116, the control section 112 disables the operation of the wireless section 117, the audio processing section 118, the switching section 119, and the ring tone generating section 123. In particular, the operation of the wireless section 117 that consumes a large amount of power is necessarily stopped. In addition, a message informing the user that the communication section 114 is not available due to insufficient battery power is displayed on the display section 115.

That is, it is possible to disable the operation of the communication section 114 and display the notice on the display section 115 by the voltage detecting section 116 and the control section 112. This message may be a character message. Or as a more intuitive indication, a cross mark (X) may be displayed on a telephone icon displayed at the top of the display screen of the display section 115.

In addition, the function of the communication section 114 can be more reliably stopped by providing a power shutdown section 126 capable of selectively shutting down the power to a section related to the function of the communication section 114.

As described above, since the mobile information device 110 according to the present embodiment includes the piezoelectric vibrator 1 in which the airtightness in the cavity C is secured, stable electrical connection between the piezoelectric vibrating reed 4 and the external electrodes 38 and 39 is secured, and operational reliability is improved, it is possible to achieve an improvement in the operational reliability and high quality of the mobile information device itself which provides stable conductivity. In addition to this, it is possible to display highly accurate clock information which is stable over a long period of time.

### (Radio-Controlled Timepiece)

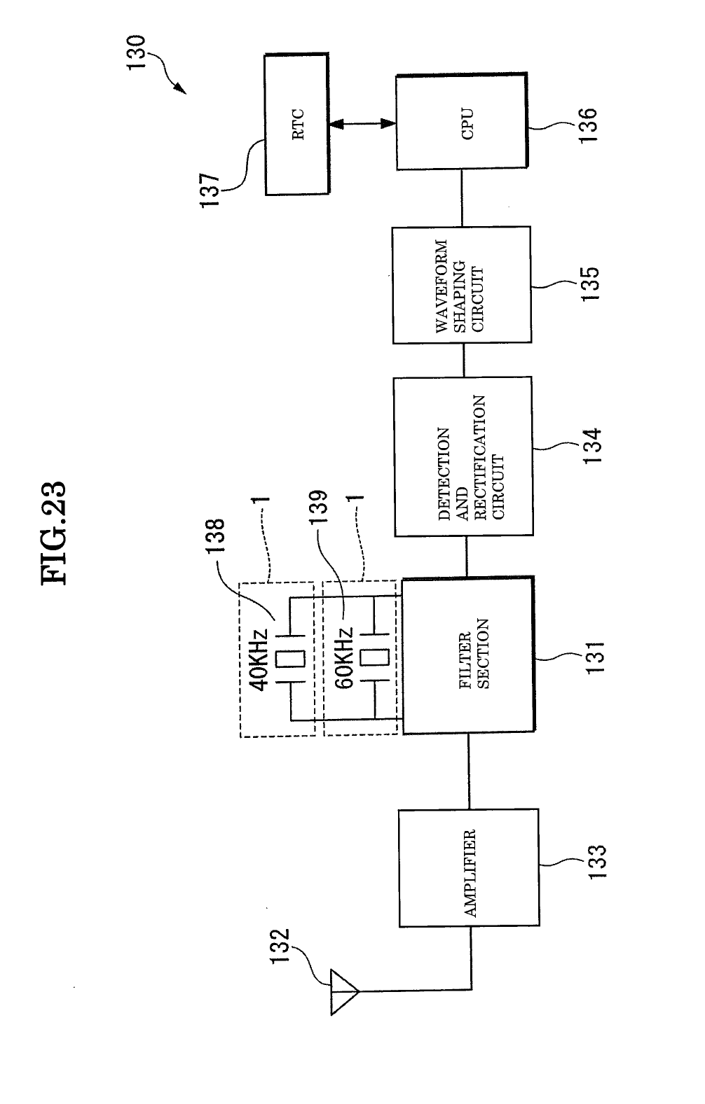

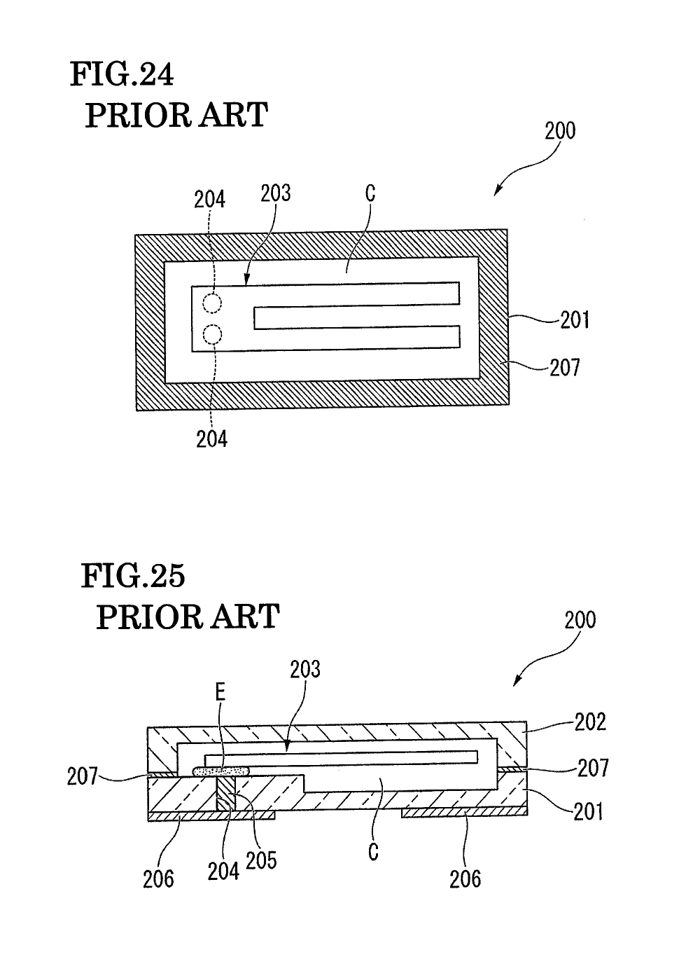

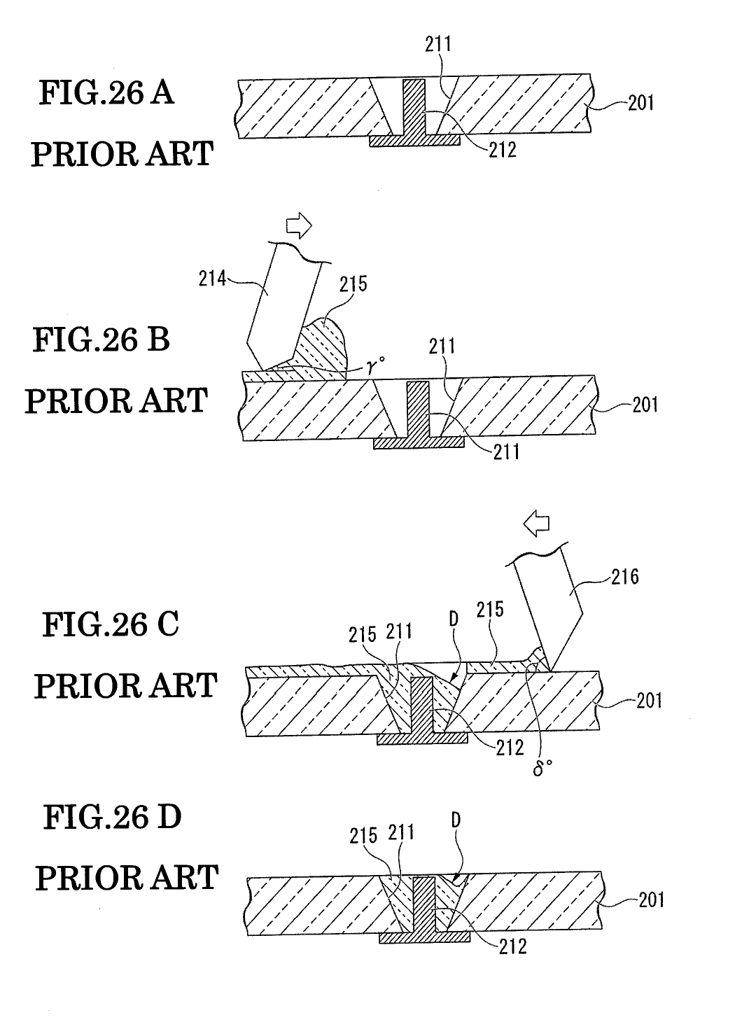

Next, a radio-controlled timepiece according to still another embodiment of the invention will be described with reference to FIG. 23.

As shown in FIG. 23, a radio-controlled timepiece 130 according to the present embodiment includes the piezoelectric vibrators 1 electrically connected to a filter section 131. The radio-controlled timepiece 130 is a timepiece with a function of receiving a standard radio wave including the clock information, automatically changing it to the correct time, and displaying the correct time.

In Japan, there are transmission centers (transmission stations) that transmit a standard radio wave in Fukushima Prefecture (40 kHz) and Saga Prefecture (60 kHz), and each center transmits the standard radio wave. A long wave with a frequency of, for example, 40 kHz or 60 kHz has both a characteristic of propagating along the land surface and a characteristic of propagating while being reflected between the ionosphere and the land surface, and therefore has a propagation range wide enough to cover the entire area of Japan through the two transmission centers.

Hereinafter, the functional configuration of the radio-controlled timepiece 130 will be described in detail.

An antenna 132 receives a long standard radio wave with a frequency of 40 kHz or 60 kHz. The long standard radio wave is obtained by performing AM modulation of the time information, which is called a time code, using a carrier wave with a frequency of 40 kHz or 60 kHz. The received long standard wave is amplified by an amplifier 133 and is then filtered and synchronized by the filter section 131 having the plurality of piezoelectric vibrators 1.

In the present embodiment, the piezoelectric vibrators 1 include crystal vibrator sections 138 and 139 having resonance frequencies of 40 kHz and 60 kHz, respectively, which are the same frequencies as the carrier frequency.

In addition, the filtered signal with a predetermined frequency is detected and demodulated by a detection and rectification circuit 134. Then, the time code is extracted by a waveform shaping circuit 135 and counted by the CPU 136. The CPU 136 reads the information including the current year, the total number of days, the day of the week, the time, and the like. The read information is reflected on an RTC 137, and the correct time information is displayed.

Because the carrier wave is 40 kHz or 60 kHz, a vibrator having the tuning fork structure described above is suitable for the crystal vibrator sections 138 and 139.

Moreover, although the above explanation has been given for the case in Japan, the frequency of a long standard wave is different in other countries. For example, a standard wave of 77.5 kHz is used in Germany. Therefore, when the radio-controlled timepiece 130 which is also operable in other countries is assembled in a portable device, the piezoelectric vibrator 1 corresponding to frequencies different from the frequencies used in Japan is necessary.

As described above, since the radio-controlled timepiece 130 according to the present embodiment includes the piezoelectric vibrator 1 in which the airtightness in the cavity C is secured, stable electrical connection between the piezoelectric vibrating reed 4 and the external electrodes 38 and 39 is secured, and operational reliability is improved, it is possible to achieve an improvement in the operational reliability and high quality of the radio-controlled timepiece itself which provides stable conductivity. In addition to this, it is possible to count the time highly accurately and stably over a long period of time.

While the embodiments of the invention have been described in detail with reference to the accompanying drawings, the specific configuration is not limited to the above-described embodiments, and various changes may be made in design without departing from the spirit of the invention.

For example, although in the above-described embodiment, the through holes 30 and 31 have a conical shape having a tapered sectional shape, they may have an approximately cylindrical shape having a straight shape rather than the tapered sectional shape.

Moreover, the core portion 7 has been described as having a circular columnar shape, it may have a rectangular columnar shape. In this case, the same operational effect can be also obtained.

In addition, in the above-described embodiment, it is preferable that the core portion 7 has approximately the same thermal expansion coefficient as the base substrate 2 (the base substrate wafer 40) and the cylindrical member 6.

In this case, when baking is performed, the three members, namely the base substrate wafer 40, the cylindrical member 6, and the core portion 7 will experience the same thermal expansion. Therefore, there will be no problems resulting from the different thermal expansion coefficients, for example, a case where excessive pressure is applied to the base substrate wafer 40 or the cylindrical member 6, thus forming cracks or the like, and a case where a gap is formed between the cylindrical member 6 and the through holes 30 and 31 or between the cylindrical member 6 and the core portion 7. Therefore, it is possible to form the penetration electrodes having higher quality, and accordingly, to achieve a further improvement in the quality of the piezoelectric vibrator 1.

For example, although the above-described embodiments have been described by way of an example of the grooved piezoelectric vibrating reed 4 in which the grooves 18 are formed on both surfaces of the vibrating arms 10 and 11 as an example of the piezoelectric vibrating reed 4, the piezoelectric vibrating reed 4 may be a type of piezoelectric vibrating reed without the grooves 18. However, since the field efficiency between the pair of the excitation electrodes 15 when a predetermined voltage is applied to the pair of excitation electrodes 15 can be increased by forming the grooves 18, it is possible to suppress the vibration loss further and to improve the vibration properties much more. That is to say, it is possible to decrease the CI value (Crystal Impedance) further and to improve the performance of the piezoelectric vibrating reed 4 further. In this respect, it is preferable to form the grooves 18.

In addition, although the embodiment has been described by way of an example of a tuning-fork type piezoelectric vibrating reed 4, the piezoelectric vibrating reed of the present invention is not limited to the tuning-fork type piezoelectric vibrating reed but may be a thickness-shear type piezoelectric vibrating reed, for example.

Moreover, although in the above-described embodiments, the base substrate 2 and the lid substrate 3 are anodically bonded by the bonding film 35, the bonding method is not limited to the anodic bonding. However, anodic bonding is preferable because the anodic bonding can tightly bond both substrates 2 and 3.

Furthermore, although in the above-described embodiments, the piezoelectric vibrating reed 4 is bonded through bumps, the bonding method is not limited to bump bonding. For example, the piezoelectric vibrating reed 4 may be bonded by a conductive adhesive agent. However, since the bump bonding allows the piezoelectric vibrating reed 4 to be floated from the upper surface of the base substrate 2, it is naturally possible to secure the minimum vibration gap necessary for vibration of the piezoelectric vibrating reed 4. Therefore, bump bonding is preferable.

The method of manufacturing the piezoelectric vibrator according to the invention can be applied to a surface mounted device (SMD)-type piezoelectric vibrator in which a piezoelectric vibrating reed is sealed in a cavity formed between two bonded substrates.

What is claimed is:

1. A method of manufacturing a piezoelectric vibrator in which a piezoelectric vibrating reed is sealed in a cavity formed between a base substrate and a lid substrate which are bonded to each other, the method comprising the steps of:
inserting a core portion of a conductive rivet member, which includes a planar base portion and the core portion extending in a direction vertical to the surface of the base portion, into a penetration hole of the base substrate and bringing the base portion of the rivet member into contact with a first surface of the base substrate;
applying a paste-like glass frit on a second surface of the base substrate and moving a first squeegee which comes into contact with the second surface with an attack angle along the second surface in one direction from one side of the penetration hole to thereby fill the glass frit in the penetration hole;
moving a second squeegee which comes into contact with the second surface with an attack angle along the second surface in a direction opposite to the one direction from the opposite side with the penetration hole on one side disposed therebetween to thereby fill the glass frit applied redundantly on the second surface in the penetration hole; and
baking and curing the glass frit.

2. The method of manufacturing the piezoelectric vibrator according to claim 1,
wherein the attack angle of the first squeegee and the attack angle of the second squeegee are set to be within the range of 5° to 45°.

3. The method of manufacturing the piezoelectric vibrator according to claim 1,
wherein the first and second squeegees include
an attack surface which is inclined at a predetermined attack angle and comes into contact with the second surface, and
an escape surface which is gradually inclined upward as it advances toward a rear side in the movement directions of the first and second squeegees from a contact portion between the second surface and the attack surface.

4. An oscillator in which the piezoelectric vibrator manufactured by the method according to claim 1 is electrically connected to an integrated circuit as an oscillating piece.

5. An electronic device in which the piezoelectric vibrator manufactured by the method according to claim 1 is electrically connected to a clock section.

6. A radio-controlled timepiece in which the piezoelectric vibrator manufactured by the method according to claim 1 is electrically connected to a filter section.
